(19) United States
(12) Patent Application Publication
(10) Pub. No.: US 2013/0161602 A1
(43) Pub. Date: Jun. 27, 2013

(54) PROCESS FOR MODIFYING ELECTRODES IN AN ORGANIC ELECTRONIC DEVICE

(71) Applicants: Mark James, Romsey (GB); Li Wei Tan, Eastleigh (GB)

(72) Inventors: Mark James, Romsey (GB); Li Wei Tan, Eastleigh (GB)

(73) Assignee: MERCK PATENT GESELLSCHAFT MIT BESCHRANKTER HAFTUNG, Darmstadt (DE)

(21) Appl. No.: 13/806,355

(22) PCT Filed: May 27, 2011
(86) PCT No.: PCT/EP2011/002621

§ 371 Date: Mar. 11, 2013

(30) Foreign Application Priority Data
Jun. 24, 2010 (EP) 10006575.4

(51) Int. Cl. H01L 51/05

(52) U.S. Cl. CPC H01L 51/0512; H01L 51/0504
USPC 257/40; 438/99

(57) ABSTRACT

The present invention relates to a process for modifying the electrodes in an organic electronic (OE) device, in particular an organic field effect transistor (OFET), and to an OE device prepared by using such a process.

The present invention relates to a process for modifying the electrodes in an organic electronic (OE) device, in particular in an organic field effect transistor (OFET), and to an OE device prepared by using such a process.

### BACKGROUND OF THE INVENTION

Organic field effect transistors (OFETs) are used in display devices and logic capable circuits. Different metals have been used as the source/drain electrodes in OFETs. A widely used electrode material is gold (Au), however, its high cost and disadvantageous processing properties have shifted the focus to possible alternatives like for example Ag, Al, Cr, Ni, Cu, Pd, Pt, Ni or Ti. Copper (Cu) is one of the possible alternative electrode materials for Au, as it has a high conductivity, a relatively low price and is easier for the usual manufacturing processes. In addition, Cu is already used in the semiconductor industry, therefore it is easier to switch the large scale production process of electronic devices to organic semiconductor (OSC) materials as a new technology, when combined with the already established Cu technology for the electrodes.

However, when using Cu as the electrode, i.e. as charge carrier injection metal for the OSC layer, there is a disadvantage due to its low work function, which is below the level of most modern OSC materials.

DE 10 2005 005 089 A1 describes an OFET comprising Cu source and drain electrodes, which are surface modified by providing a Cu oxide layer thereon. However, since the Cu in an ambient atmosphere tends to oxidize to Cu₂O and then to CuO and further to Cu hydroxides, this can create a non-metal conductive layer on the Cu electrode which results in limited charge carrier injection into the OSC layer.

In prior art there are known methods of metal or metal oxide electrode modification in order to improve charge carrier injection, which are based e.g. on thiol compounds.

For example, US 2008/0315191 A1 discloses an organic TFT (OTFT) comprising source and drain electrodes formed of a metal oxide, wherein the electrode surfaces are subjected to surface treatment by applying a thin film, with a thickness of 0.3 to 1 molecular layer, of a thiol compound, for example pentafluorobenzenethiol, perfluoroalkylthiol, trifluoromethanethiol, pentafluoroethanethiol, heptafluoropropanethiol, nonafluorobutanethiol, sodium butanethiol, sodium butanoate thiol, sodium butanol thiol or aminothiophenol. However this approach is effective mainly for Au or Ag electrodes, but not very effective for Cu electrodes because, compared to an Au surface, on a Cu surface the thiol groups form weaker chemical bonds.

It is therefore an aim of the present invention to provide an improved process for preparing an OE device containing a metal electrode or a metal charge injection layer and an OSC layer provided thereon, which allows to increase the work function of the electrode or charge injection layer and its efficiency of charge carrier injection into the OSC layer and thus improve the overall device performance. The process should overcome the drawbacks of metal electrodes known from prior art, like low work function and low oxidative stability. Another aim is to provide improved electrodes and charge injection layers based on metals for use in OE devices, in particular OFETs and OLEDs, and methods for their preparation. Another aim is to provide improved OE devices, in particular OFETs and OLEDs, containing improved electrodes with higher work function. The methods and devices should not have the drawbacks of prior art methods and allow time-, cost- and material-effective manufacture at large scale. Other aims of the present invention are immediately evident to the expert from the following description.

It was found that these aims can be achieved by providing a process as described in the present invention. In particular, the present invention is related to a chemistry-based treatment process for metal electrodes which improves their work function and their charge carrier injection property into an OSC layer coated thereon. This is achieved by depositing onto an electrode comprising a first metal, for example Cu, a layer of a second metal having a higher normal potential or redox potential than the first metal (i.e. a metal that is nobler than the first metal), like for example Ag. The second metal is preferably deposited by electroless plating using an ion exchange process, for example by immersing the electrode in a bath containing ions of the second metal.

In order to improve the electrode work function the second metal is selected to have a higher work function than the first metal, and/or the second metal layer is subjected to a surface treatment process, for example by applying a SAM layer of an organic functional molecule that increases the electrode work function, e.g. an organic molecule that shows better interaction with the second metal than with the first metal. Since only a thin layer of the second metal is needed, more expensive metals with higher work function or being nobler than the first metal can be used without significantly increasing the device manufacturing costs. Also, this process enables to overcome the disadvantage that on the surface of e.g. Cu typical SAM treatment materials like thiols may form weaker chemical bonds than on the surface of e.g. Au or Ag.

In prior art the method of plating e.g. Ag on Cu metal, and the method of applying SAMs on Cu or Ag metal layers, have been suggested as possible ways to improve the finishing and inertness of metal surface, or for example in printed circuit boards (PCBs), also known as printed wire boards (PWBs) to improve the solderability and corrosion resistance. However, it has hitherto not been suggested to use these methods also in the manufacturing process of OE devices, like OFETs, OPV devices, or OLEDs, for improving the electrode work function.

US 2009/0121192 A1 discloses a method for enhancing the corrosion resistance of an article comprising an Ag coating deposited on a solderable Cu substrate. This is achieved by exposing the Cu substrate, which has an immersion-plated Ag coating thereon, to an anti-corrosion composition that contains a multifunctional molecule having at least one organic functional group that interacts with and protects Cu surfaces, and at least one organic functional group that interacts with and protects Ag surfaces. However, this document does not contain any hint or suggestion how to improve the electrode work function in an OE device, where an OSC layer is deposited onto an electrode, in order to enhance charge carrier injection into the OSC layer.

WO 02/29132 A1 discloses a method for improving the solderability of Cu surfaces on printed circuit boards, by exposing the Cu surface to a bath for electroless plating of Ag by way of charge exchange reaction, wherein the bath contains at least one silver halide complex and does not contain any reducing agent for Ag⁺ ions. Again, there is no hint how to overcome the problem of improving the electrode work function in an OE device, where an OSC layer is deposited onto the electrode, in order to enhance charge carrier injection into the OSC layer.

### SUMMARY OF THE INVENTION

The invention relates to a process for modifying the electrodes in an organic electronic (OE) device, comprising the steps of

a) providing an electrode, or two or more electrodes, comprising a first metal having a normal electrode potential,

b) depositing onto said electrode(s) a layer of a second metal having a normal electrode potential which is higher than the normal electrode potential of the first metal,

c) optionally exposing said layer of said second metal to a composition comprising an organic compound containing a functional group that interacts with the surface of said second metal, and

d) depositing onto the electrode(s), and/or in the area between said electrodes, an organic semiconductor layer.

The invention further relates to a process of preparing an OE device comprising the above steps a), b), d) and optionally c).

The invention further relates to an OE device obtainable or obtained by a process as described above and below.

Preferably said electrode is a source or drain electrode or a charge injection layer.

Preferably the OE device is selected from the group consisting of organic field effect transistors (OFET), organic thin film transistors (OTFT), organic complementary thin film transistors (CTFT), components of integrated circuitry (IC), radio frequency identification (RFID) tags, organic light emitting diodes (OLED), electroluminescent displays, flat panel displays, backlights, photodetectors, sensors, logic circuits, memory elements, capacitors, organic photovoltaic (OPV) cells, charge injection layers, Schottky diodes, planarising layers, antistatic films, conducting substrates or patterns, photoconductors, photoreceptors, electrophotographic devices and xerographic devices, very preferably a top gate or bottom gate OFET.

### BRIEF DESCRIPTION OF THE DRAWINGS

FIG. 1 exemplarily and schematically illustrates the definition of work function and the Fermi level of gold (Au) and calcium (Ca).

FIG. 2 exemplarily and schematically illustrates the hole injection barrier between the Au electrode and the HOMO level of a p-type OSC; and the electron injection barrier between the Ca electrode and the LUMO level of an n-type OSC.

FIG. 3 schematically depicts a typical top gate OFET according to the present invention.

FIG. 4 schematically depicts a typical bottom gate OFET according to the present invention.

FIGS. 5a-d show the transfer characteristics of OFET prepared in accordance with the process described in Example 1.

FIG. 6 shows the transfer characteristic over time measurement of an OFET prepared in accordance with the process described in Example 1.

FIG. 7 shows the saturated mobilities versus V_{G} measured over 24 hours of continuous bias stress of an OFET prepared in accordance with the process described in Example 1.

### DETAILED DESCRIPTION OF THE INVENTION

Hereinafter the terms “electrode (layer)” and “charge injection layer” are used interchangeably. Thus reference to an electrode (layer) also includes reference to a charge injection layer and vice versa.

The term “normal electrode potential”, also known as “standard electrode potential”, or “redox potential”, means the electromotive force of a cell in which the electrode on the left is a standard hydrogen electrode (SHE), also known as normal hydrogen electrode (NHE), and the electrode on the right is the electrode in question (see IUPAC Green Book, 2^{nd} ed., p. 61; PAC, 1996, 68, 957). The standard (or normal) electrode potential E⁰ of hydrogen is defined to be zero at all temperatures. Potentials of any other electrodes are compared with that of the standard hydrogen electrode at the same temperature. Metals having a high normal electrode potential are also referred to as noble metals.

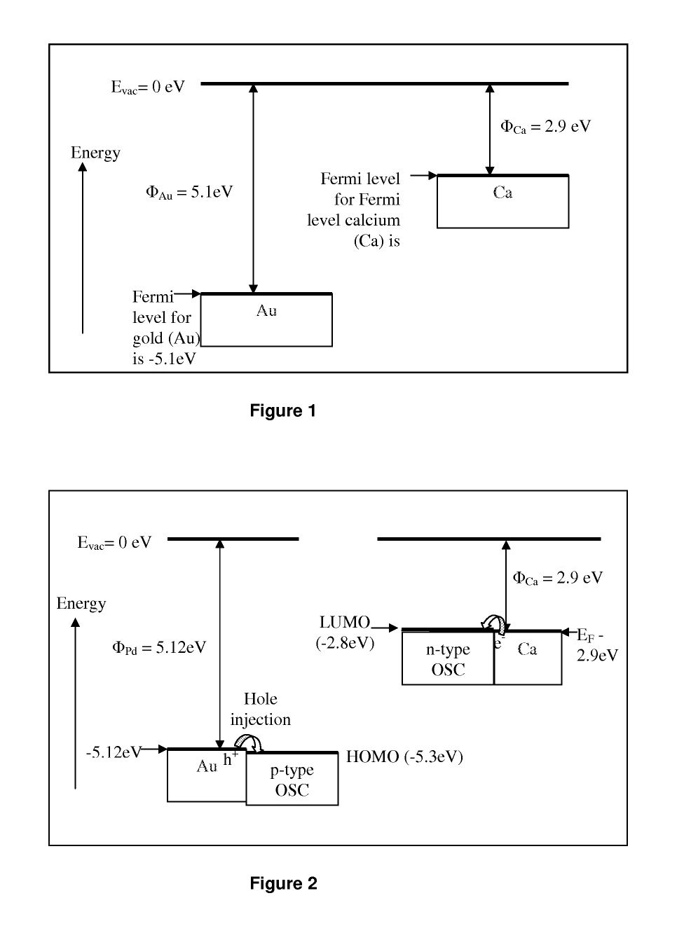

The following definitions of “work function” shall apply. The work function is the minimum energy (usually measured in electron volts, eV) needed to remove an electron from a solid to a point outside the solid surface (or energy needed to remove an electron from the Fermi level into vacuum level). Since the vacuum level is always referred to as energy level of 0 eV, the Fermi level is always defined as a negative value as shown in FIG. 1. Even though the Fermi level is a negative value, the work function (Φ) is defined as Φ=E_{vac}−E_{Fermi} for the respective material, so that it will be usually a positive value. For example, the work function for gold (Au) is 5.1 eV and the Fermi level of Au is −5.1 eV. Therefore, Au is a high work function metal while calcium (Ca), which has Φ_{Ca}=2.9 eV, is a low work function metal.

In the periodic table, high work function metals include platinum (Φ_{Pt}=5.65 eV), palladium (Φ_{Pd}=5.12 eV), nickel (Φ_{Ni}=5.15 eV), and iridium (Φ_{Ir}=5.27 eV). The low work function metals are basically alkaline metals such as lithium (Φ_{Li}=2.9 eV), sodium (Φ_{Na}=2.75 eV), potassium (Φ_{K}=2.30 eV), cesium (Φ_{Cs}=2.14 eV) and alkaline earth metals such as calcium (Φ_{Ca}=2.9 eV) and barium (Φ_{Ba}=2.7 eV).

All the work function values of metals mentioned here are based on the reference: Herbert B. Michaelson “The work function of the elements and its periodicity”, Journal of Applied Physics, 48(11), November 1977.

In case of OSC molecules, the work function is not suitable to describe the semiconductor. The highest occupied molecular orbital (HOMO) level of an OSC, which corresponds to the valence band in an inorganic material, and the lowest unoccupied molecular orbital (LUMO) level of an OSC, which corresponds to the conduction band in an inorganic material, are the energy levels of the orbital in the OSC molecules that are involved with the charge transport. For a p-type OSC, the hole transport happens in HOMO energy level while for an n-type OSC, the transport happens in LUMO level.

To get a better charge injection for better device performance in OFETs and OLEDs, the work function of the electrodes have to match the HOMO (p-type) or LUMO (n-type) energy level of the OSC. For example, Pd (Φ_{Pd}=5.15 eV) and Pt (Φ_{Pt}=5.65 eV) are suitable electrodes for p-type devices since the HOMO level of the OSC is around −5.3 eV (see FIG. 2). However, Pd and Pt are expensive metals to be used as an electrode.

For an n-type OSC device, Ca is a good electrode material since the work function is around 2.9 eV which is matching with the LUMO level of the OSC (typical LUMO of an OSC is in between −2.8 to −3.3 eV). However, Ca is highly sensitive to the oxygen and the moisture.

Au and Ag are often used as electrode material, however, it is desirable to replace these metals with Cu to reduce the fabrication costs. However, Cu is a low work function material with a typical work function of 4.6 eV, whereas for most OSC materials, the typical HOMO level is around −5.3 to −5.8 eV. Therefore, it is desirable to increase the electrode work function of the electrode in order to get closer to the HOMO level of the OSC material, and to improve the charge carrier injection from the electrode into the OSC layer.

Many electrode materials cannot be used in the OE devices due to limitations in the work function, stability and high raw material cost. For example, Ag has a work function of 4.3 eV, which is too low for use as the electrode in a p-type OE device. In order to improve and increase the work function of Ag electrodes, self-assembled monolayer (SAM) materials, for example thiols like pentafluorobenzenethiol, can be applied onto the electrode.

For low cost materials such as Cu (Φ_{Cu}=4.65 eV), the work function is relatively low, therefore these metals are also preferably subjected to SAM treatment to improve the work function. Without modification by SAMs on these metals, the OE device typically shows a high injection barrier which lowers the device performance.

Pt and Pd, on the other hand, are among the high work function and stable metals that can be used as electrode material. However, their raw material cost is too high for industrial application at large scale.

This invention offers a solution to the above-mentioned problems by providing a low cost process, wherein the work function of electrode materials that are cheap, but do have only a low work function, can be increased so that it is closer to the HOMO level of the OSC material. The process includes a metal exchange process on the electrode surface, optionally followed by an SAM treatment process. As a result, electrodes with a high work function can be obtained, which have similarly high work function as electrodes consisting entirely of high work function (and high cost) materials, while keeping the processing cost to a much lower level.

The process according to the present invention comprises the steps of

a) providing an electrode, or two or more electrodes, like for example the source and drain electrode in an OFET or OTFT, preferably on a substrate, said electrode(s) comprising a first metal having a normal electrode potential,

b) depositing onto said electrode(s) a layer of a second metal that has a normal electrode potential, that is higher than the normal electrode potential of the first electrode, i.e. the second metal is a nobler metal than the first metal,

c) optionally exposing said layer of second metal to a composition comprising an organic compound containing a functional group that interacts with the surface of said second metal, so that the organic compound forms a layer, preferably a self assembled monolayer (SAM), on the second metal, and

d) depositing onto the electrode(s), and/or in the area between said electrodes, an organic semiconductor layer.

If two electrodes are provided, for example the source and drain electrodes in an OFET or OTFT, the OSC layer is preferably deposited in the area between the source and drain electrodes (also known as the channel area) and optionally also on top of the electrodes.

Preferred embodiments of the present invention include, but are not limited to, those listed below, including any combination of two or more of these embodiments:
the second metal has a higher work function than the first metal,
the first metal is selected from the group consisting of Cu, Al, Zn and Sn,
the second metal is selected from the group consisting of Ag, Au, Co, Cu, Ir, Ni, Pd, Pt, Rh, Re and Se,
the layer of the second metal is deposited by electroless plating,
the layer of the second metal is deposited by an ion exchange process,
the layer of the second metal is deposited by immersing the electrode in a bath containing ions of the second metal,
the bath does not contain any reducing agent for the ions of the second metal,
the bath contains one or more additives selected from the group consisting of ion complexing agents, buffering agents, stabilisers, salts, acids and bases,
the bath contains an organic compound containing a functional group that interacts with the surface of said second metal,
the second metal has a similar or lower work function than the first metal, and onto the layer of the second metal there is applied a self assembled monolayer (SAM) of an organic compound containing a functional group that interacts with the surface of said second metal,
the organic compound contains a functional group that shows better interaction with the second metal than with the first metal,
the organic compound contains a functional group that interacts with the organic semiconductor,
the organic compound containing a functional group that interacts with the surface of said second metal is selected from the group consisting of aliphatic or aromatic thiols, aliphatic or aromatic dithiols, oligothiophenes, oligophenylenes, aliphatic or aromatic disulfides like for example cyanoquinoalkanedisulfide, silanes, chlorosilanes, silazanes like for example hexamethyldisilizane (HMDS), triazoles, tetrazoles, imidazoles and pyrazoles, carboxylic acids like for example eicosanoic acid, phosphonic acids, phosphonates like for example 9-anthracene phosphonate, all of which are optionally substituted, and metal oxides like for example silver oxide or molybdenum oxide,
the process additionally comprises, after steps a)-d) as described above and below, the following steps: depositing a gate insulator layer onto the OSC layer, depositing a gate electrode onto the gate insulator layer, and optionally depositing a passivation layer onto the gate electrode,
the process additionally comprises, before steps a)-d) as described above and below, the following steps: depositing a gate electrode onto a substrate, depositing a gate insulator layer onto the gate electrode, wherein the electrode(s) in step a) are provided onto the gate insulator layer, and optionally the process additionally comprises, after step d) as described above and below, the step of depositing a passivation layer onto the OSC layer.

Further suitable and preferred methods for plating nobler metal onto a less novel metal, which can be used in the process according to the present invention, are also disclosed in WO 02/29132 A1, the entire disclosure of which is incorporated into this application by reference.

Preferably, the electrode of the first metal, e.g. Cu, is cleaned, for example by washing with suitable and known agents, and then immersed in an immersion plating bath containing for example Ag⁺ ions or ions of another nobler metal. This results the replacing of the first metal (Cu) with the second metal (Ag) on the surface via an ion exchange reaction. The immersion bath preferably contains e.g. a suitable salt of the second metal, like AgNO₃, and preferably does not contain any reducing agent for the ions of the second metal (Ag⁺ ions). After immersion for a certain time, for example 1-5 min, the electrode is removed from the bath and optionally cleaned e.g. by rinsing with deionized water.

In a preferred embodiment of the present invention, a self assembled monolayer (SAM) of organic molecules is applied to the electrode after application of the second metal layer, which contain functional group that interacts with the second metal, in order to further increase the work function and/or stability of the electrode, and to improve interaction with the OSC layer. The SAM molecules are selected for example from thiols. The SAM layer is preferably applied by immersing the electrode for a given period of time, for example 1 min, into a solution containing the SAM molecules. The excessive SAM solution is then preferably spun off or washed away, for example with a high volatile organic solvent such as isopropanol.

Suitable and preferred SAM molecules are for example disclosed in US 2009/0121192 A1, the entire disclosure of which is incorporated into this application by reference.

Subsequently, an OSC layer is deposited on the electrode, followed by gate electrode deposition for example by an evaporation process.

The process according to the present invention is not restricted to the application of Ag on Cu, but can also be applied to other metal-based electrodes to reduce the cost of working devices. For example Pt, Pd, Se or Au can be applied on Cu, or on metals other than Cu.

The second (high work function) metal can be applied by immersing the electrode in a bath containing ions of the second metal, or an ion complex, where the second metal will form a thin layer of the first metal as a result of an ion exchange.

The bath for the metal ion exchange process is preferably a solution, for example an organic or aqueous solution, preferably an aqueous solution. The concentration of the metal ions is preferably <1 mM in aqueous solution. The immersion time can be varied from a few second to a few hours. The bath is not restricted only to the compound for the metal exchange, but can additionally contain SAM molecules such as aromatic or aliphatic thiols (R—SH), dithiols (HS—R—SH), thioacetyls (R—S-Ac), disulfides (R—S—S—R), oligothiophenes, oligophenylenes, or chlorosilanes, wherein R is an aliphatic or aromatic moiety and Ac is acetyl.

The surface of the electrode after the metal exchange may consist of the pure second metal (like Ag), or may consist of or contain one or more oxides of the second metal (like AgO or Ag₂O) through oxidation.

The immersion bath preferably contains a metal salt. Suitable and preferred salts include, without limitation, Au salts such as AuCN or [KAu(CN)₂], Pd salts such as PdCl₂, Pt salts such as K₂PtCl₄, Ag salts such as AgNO₃ or AgCN. or suitable salts of other high work function metals like Ir (Φ_{Ir}=5.27 eV), Re (Φ_{Re}=4.96 eV), Rh (Φ_{Rh}=4.98 eV), Co (Φ_{Co}=5.0 eV), or Ni (Φ_{Ni}=5.15 eV).

Other components or additives can also be added to the immersion bath, such as buffer solutions and stabilisers. For example, KOH or KBH₄ can be added to an immersion bath containing Au ions, and hydrazine hydrate can be added to an immersion bath containing Pt salts.

The immersion bath can also contain one or more compounds selected from the group consisting of SAM molecules, buffers like ammonium acetate or NH₄Cl, stabilisers like disodium EDTA, KCN or thiourea, organic or inorganic acids like acetic acid, sulphuric acid, citric acid or HCl, or bases like NH₄OH or NaOH.

The extent of the metal exchange can be tuned by varying the concentration of the metal ions. Metal exchange can occur already at low concentrations (0.001 mM to 0.1 M), where a colour change may not even be visible to the naked eye. For example, a metal exchange of Cu by Ag can be achieved by immersion in a 0.1 mM AgNO₃ bath, at which concentration no colour change in the Cu electrode is observed.

The concentration of the ions or salt of the second metal in the immersion bath or immersion solution is preferably from 0.0001 to 10 mM, most preferably from 0.01 to 1 mM, especially preferably when using Ag or Pd as second metal.

Different temperatures can be applied to optimise the ion exchange and SAM process and/or to shorten the processing time. The temperature of the immersion bath can be selected within a broad range, for example from −30° C. to 100° C., depending on the optimum conditions.

The thickness of the layer of the second metal on the electrode is preferably from 0.3 molecular layers to 10 nm.

The thickness of the SAM layer provided on the layer of the second metal, after removal of solvents, is preferably from 1 to 10 molecular layers.

As first metal of the electrode preferably Cu is used. It is also possible to use metals other than Cu, like for example Al, Zn or Sn.

Instead of a metal electrode in the shape of a solid film, other physical forms or shapes of electrodes can also be used in the process of the present invention. For example it is possible to use an electrode consisting of or comprising a layer that contains nanoparticles, nanowires or nanorods of the first metal. In the metal exchange process a layer of the second metal is then applied to these nanoparticles, nanowires or nanorods, and afterwards an OSC layer is applied over the electrode layer, or in the area between two or more of said electrodes.

The process according to this invention can also be used in the manufacture of organic light-emitting diodes (OLEDs), organic photovoltaic (OPV) devices, or organic photodetectors.

In addition to an increased work function, the process according to the present invention can also provide further beneficial effect such as improved corrosion resistance, reduced electrochemical migration, reduced contact resistance, environmental benefits (e.g. if no volatile solvents are used in the bath), lower device production costs, and improved reliability of the device production process.

The electrodes containing the first metal are preferably provided on a substrate, to which they can be applied by solvent-based or liquid coating methods, such as spray-, dip-, web- or spin-coating, or by vacuum or vapour deposition methods like physical vapour deposition (PVS) or chemical vapour deposition (CVD) or sublimation. Suitable substrates and deposition methods are known to the skilled person from the literature.

Preferably, the electrodes are subjected to a preliminary washing step before the metal plating with the second metal. The washing step preferably includes one or more of an acidic washing step with organic or inorganic acids like for example acetic acid, citric acid or HCl, a step of exposition to a plasma like for example an argon plasma, oxygen plasma or CFₓ plasma, an UV and/or ozone treatment step, or a base or oxidizing agent washing step with for example hydrogen peroxide.

When preparing a top gate (TG) transistor, source and drain electrodes are usually first applied onto a substrate and subjected to a metal exchange and optional SAM treatment, followed by OSC deposition. Then a gate insulator layer is applied onto the OSC layer, and a gate electrode is applied onto the gate insulator layer.

When preparing a bottom gate (BG) transistor, usually first a gate electrode is applied onto a substrate and a gate insulator layer is applied onto the gate electrode. Source and drain electrodes are then applied onto the gate insulator and subjected to the metal exchange and optional SAM treatment process, followed by OSC deposition.

The exact process conditions can be easily adopted and optimised to the corresponding insulator and OSC materials used.

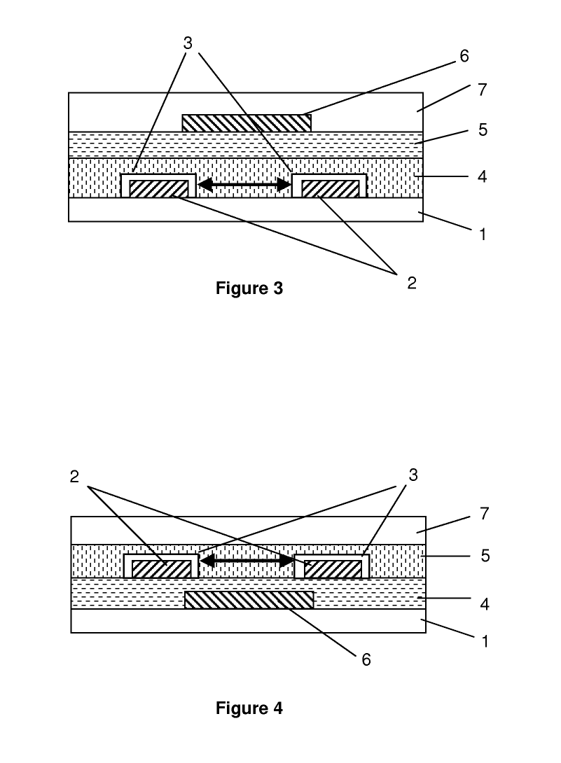

FIG. 3 is a schematic representation of a typical TG OFET according to the present invention, including a substrate (1), source (S) and drain (D) electrodes (2) containing a first metal, a layer of a second metal (3) and optionally an SAM layer (not shown) provided on the S/D electrodes (2), a layer of OSC material (4), a layer of dielectric material (5) as gate insulator layer, a gate electrode (6), and an optional passivation or protection layer (7) to shield the gate electrode (6) from further layers or devices that may be later provided, or to protect it from environmental influence. The area between the source and drain electrodes (2), as indicated by the double arrow, is the channel area.

FIG. 4 is a schematic representation of a typical BG, bottom contact OFET according to the present invention, including a substrate (1), a gate electrode (6), a layer of dielectric material (5) as gate insulator layer, source (S) and drain (D) electrodes (2) containing a first metal, a layer of a second metal (3) and optionally an SAM layer provided on the S/D electrodes (2), a layer of OSC material (4), and an optional protection or passivation layer (7) to shield the OSC layer (4) from further layers or devices that may be later provided, or to protect it from environmental influence.

The OSC materials and methods for applying the OSC layer can be selected from standard materials and methods known to the person skilled in the art, and are described in the literature.

The OSC material can be an n- or p-type OSC, which can be deposited by vacuum or vapor deposition, or preferably deposited from a solution. Preferably OSC materials are used which have a FET mobility of greater than 1×10⁻⁵ cm²V⁻¹s⁻¹.

The OSC is used for example as the active channel material in an OFET or a layer element of an organic rectifying diode. OSCs that are deposited by liquid coating to allow ambient processing are preferred. OSCs are preferably spray-, dip-, web- or spin-coated or deposited by any liquid coating technique. Ink-jet deposition is also suitable. The OSC may optionally be vacuum or vapor deposited.

The semiconducting channel may also be a composite of two or more of the same type (i.e. p-type or n-type) of OSCs. Furthermore, a p-type OSC may be mixed with an n-type OSC for the effect of doping the layer. Multilayer OSCs may also be used. For example the OSC may be intrinsic near the insulator interface, and a highly doped region can additionally be coated next to the intrinsic layer.

The OSC may be a monomeric compound (also referred to as “small molecule”, as compared to a polymer or macromolecule) or a polymeric compound, or a mixture, dispersion or blend containing one or more compounds selected from either or both of monomeric and polymeric compounds.

In case of monomeric materials, the OSC is preferably a conjugated aromatic molecules, and contains preferably at least three aromatic rings. Preferred monomeric OSCs are selected form the group consisting of conjugated aromatic molecules containing 5-, 6- or 7-membered aromatic rings, more preferably containing 5- or 6-membered aromatic rings.

In these conjugated aromatic molecules, each of the aromatic rings optionally contains one or more hetero atoms selected from Se, Te, P, Si, B, As, N, O or S, preferably from N, O or S. Additionally or alternatively, in these conjugated aromatic molecules, each of the aromatic rings is optionally substituted with alkyl, alkoxy, polyalkoxy, thioalkyl, acyl, aryl or substituted aryl groups, halogen, particularly fluorine, cyano, nitro or an optionally substituted secondary or tertiary alkylamine or arylamine represented by —N(R³)(R⁴), where R³ and R⁴ each independently is H, an optionally substituted alkyl group, or an optionally substituted aryl, alkoxy or polyalkoxy group. Where R³ and R⁴ is an alkyl or aryl group, these are optionally fluorinated.

In these conjugated aromatic molecules, the aromatic rings are optionally fused or are optionally linked to each other by a conjugated linking group such as —C(T¹)=C(T²)-, —C≡C—, —N(R′)—, —N═N—, (R′)═N—, —N═C(R′)—, wherein T¹ and T² each independently represent H, Cl, F, —CN or a C₁-C₁₀ alkyl group, preferably a C₁₋₄ alkyl group; R′ represents H, an optionally substituted C₁-C₂₀ alkyl group or an optionally substituted C₄-C₃₀ aryl group. Where R′ is an alkyl or aryl group, these are optionally fluorinated.

Further preferred OSC materials that can be used in this invention include compounds, oligomers and derivatives of compounds selected from the group consisting of conjugated hydrocarbon polymers such as polyacene, polyphenylene, poly(phenylene vinylene), polyfluorene including oligomers of those conjugated hydrocarbon polymers; condensed aromatic hydrocarbons such as tetracene, chrysene, pentacene, pyrene, perylene, coronene, or soluble, substituted derivatives of these; oligomeric para substituted phenylenes such as p-quaterphenyl (p-4P), p-quinquephenyl (p-5P), p-sexiphenyl (p-6P), or soluble substituted derivatives of these; conjugated heterocyclic polymers such as poly(3-substituted thiophene), poly(3,4-bisubstituted thiophene), optionally substituted polythieno[2,3-b]thiophene, optionally substituted polythieno[3,2-b]thiophene, poly(3-substituted selenophene), polybenzothiophene, polyisothianapthene, poly(N-substituted pyrrole), poly(3-substituted pyrrole), poly(3,4-bisubstituted pyrrole), polyfuran, polypyridine, poly-1,3,4-oxadiazoles, polyisothianaphthene, poly(N-substituted aniline), poly(2-substituted aniline), poly(3-substituted aniline), poly(2,3-bisubstituted aniline), polyazulene, polypyrene; pyrazoline compounds; polyselenophene; polybenzofuran; polyindole; polypyridazine; benzidine compounds; stilbene compounds; triazines; substituted metallo- or metal-free porphines, phthalocyanines, fluorophthalocyanines, naphthalocyanines or fluoronaphthalocyanines; C₆₀ and C₇₀ fullerenes; N,N′-dialkyl, substituted dialkyl, diaryl or substituted diaryl-1,4,5,8-naphthalenetetracarboxylic diimide and fluoro derivatives; N,N′-dialkyl, substituted dialkyl, diaryl or substituted diaryl 3,4,9,10-perylenetetracarboxylicdiimide; bathophenanthroline; diphenoquinones; 1,3,4-oxadiazoles; 11,11,12,12-tetracyanonaptho-2,6-quinodimethane; α,α′-bis(dithieno[3,2-b2′,3′-d]thiophene); 2,8-dialkyl, substituted dialkyl, diaryl or dialkynyl anthradithiophene; 2,2′-bibenzo[1,2-b:4,5-b′]dithiophene. Preferred compounds are those from the above list and derivatives thereof which are soluble in organic solvents.

Especially preferred OSC materials are selected from the group consisting of polymers and copolymers comprising one or more repeating units selected from thiophene-2,5-diyl, 3-substituted thiophene-2,5-diyl, selenophene-2,5-diyl, 3-substituted selenophene-2,5-diyl, optionally substituted thieno[2,3-b]thiophene-2,5-diyl, optionally substituted thieno[3,2-b]thiophene-2,5-diyl, optionally substituted 2,2′-bithiophene-5,5′-diyl, optionally substituted 2,2′-biselenophene-5,5′-diyl.

Further preferred OSC materials are selected from the group consisting of substituted oligoacenes such as pentacene, tetracene or anthracene, or heterocyclic derivatives thereof, like 6,13-bis(trialkylsilylethynyl)pentacenes or 5,11-bis(trialkylsilylethynyl)anthradithiophenes, as disclosed for example in U.S. Pat. No. 6,690,029, WO 2005/055248 A1 or U.S. Pat. No. 7,385,221.

In another preferred embodiment of the present invention the OSC layer comprises one or more organic binders to adjust the rheological properties as described for example in WO 2005/055248 A1, in particular an organic binder which has a low permittivity, E, at 1,000 Hz of 3.3 or less.

The binder is selected for example from poly(alpha-methylstyrene), polyvinylcinnamate, poly(4-vinylbiphenyl) or poly(4-methylstyrene, or blends thereof. The binder may also be a semiconducting binder selected for example from polyarylamines, polyfluorenes, polythiophenes, polyspirobifluorenes, substituted polyvinylenephenylenes, polycarbazoles or polystilbenes, or copolymers thereof. A preferred dielectric material for use in the present invention preferably comprises a material with a low permittivity of between 1.5 and 3.3 at 1000 Hz, such as for example Cytop™809M commercially available from Asahi Glass.

The transistor device according to the present invention may also be a complementary organic TFT (CTFT) comprising both a p-type semiconducting channel and an n-type semiconducting channel.

The process according to the present invention is not limited to OFETs or OTFTs, but can also be used in the manufacture of any OE device comprising a charge injection layer, like for example OLEDs or OPV devices. The skilled person can easily make modifications or changes to the process as described above and below, in order to use it for the manufacture of other types of OE devices.

For example, the process according to the present invention can also be applied to an electrode in an OPV device, like for example in a bulk heterojunction (BHJ) solar cell. The OPV device can be of any type known from the literature [see e.g. Waldauf et al., Appl. Phys. Lett. 89, 233517 (2006)].

A preferred OPV device according to the present invention comprises:
a low work function electrode (for example a metal, such as aluminum), and a high work function electrode (for example ITO), one of which is transparent,
a layer (also referred to as “active layer”) comprising a hole transporting material and an electron transporting material, preferably selected from OSC materials, situated between the low work function electrode and the high work function electrode; the active layer can exist for example as a bilayer or two distinct layers or blend or mixture of p-type and n-type semiconductor, forming a bulk heterojunction (BHJ) (see for example Coakley, K. M. and McGehee, M. D. Chem. Mater. 2004, 16, 4533),
an optional conducting polymer layer, for example comprising a blend of PEDOT:PSS (poly(3,4-ethylenedioxythiophene): poly(styrenesulfonate)), situated between the active layer and the high work function electrode, to modify the work function of the high work function electrode to provide an ohmic contact for holes,
an optional coating (for example of LiF) on the side of the low work function electrode facing the active layer, to provide an ohmic contact for electrons,
   wherein at least one of the electrodes, preferably the high work function electrode, is subjected to a process according to the present invention as described above and below.

Another preferred OPV device according to the present invention is an inverted OPV device that comprises:
a low work function electrode (for example a metal, such as gold), and a high work function electrode (for example ITO), one of which is transparent,
a layer (also referred to as “active layer”) comprising a hole transporting material and an electron transporting material, preferably selected from OSC materials, situated between the low work function electrode and the high work function electrode; the active layer can exist for example as a bilayer or two distinct layers or blend or mixture of p-type and n-type semiconductor, forming a BHJ,
an optional conducting polymer layer, for example comprising a blend of PEDOT:PSS, situated between the active layer and the low work function electrode to provide an ohmic contact for electrons,
an optional coating (for example of TiOₓ) on the side of the high work function electrode facing the active layer, to provide an ohmic contact for holes,
   wherein at least one of the electrodes, preferably the high work function electrode, is subjected to a metal exchange and optional SAM treatment process according to the present invention as described above and below.

Thus, in the OPV devices of the present invention preferably at least one of the electrodes, preferably the high work function electrode, is covered, on its surface facing the active layer, by a layer comprising a second metal and optionally an SAM layer, which are applied by a process according to the present invention as described above and below.

The OPV devices of the present invent invention typically comprise a p-type (electron donor) semiconductor and an n-type (electron acceptor) semiconductor. The p-type semiconductor is for example a polymer like poly(3-alkyl-thiophene) (P3AT), preferably poly(3-hexylthiophene) (P3HT), or alternatively another selected from the groups of preferred polymeric and monomeric OSC material as listed above. The n-type semiconductor can be an inorganic material such as zinc oxide or cadmium selenide, or an organic material such as a fullerene derivate, for example (6,6)-phenyl-butyric acid methyl ester derivatized methano C₆₀ fullerene, also known as “PCBM” or “C₆₀PCBM”, as disclosed for example in G. Yu, J. Gao, J. C. Hummelen, F. Wudl, A. J. Heeger, Science 1995, Vol. 270, p. 1789 ff and having the structure shown below, or an structural analogous compound with e.g. a C₇₀ fullerene group (C₇₀PCBM), or a polymer (see for example Coakley, K. M. and McGehee, M. D. Chem. Mater. 2004, 16, 4533).

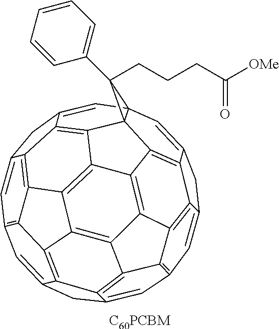

A preferred material of this type is a blend or mixture of a polymer like P3HT or another polymer selected from the groups listed above, with a C₆₀ or C₇₀ fullerene or modified fullerene like PCBM. Preferably the ratio polymer:fullerene is from 2:1 to 1:2 by weight, more preferably from 1.2:1 to 1:1.2 by weight, most preferably 1:1 by weight. For the blended mixture, an optional annealing step may be necessary to optimize blend morpohology and consequently OPV device performance.

Preferably the deposition of individual functional layers in the process as described above and below, like the OSC layer and the insulator layer, is carried out using solution processing techniques. This can be done for example by applying a formulation, preferably a solution, comprising the OSC or dielectric material, respectively, and further comprising one or more organic solvents, onto the previously deposited layer, followed by evaporation of the solvent(s). Preferred deposition techniques include, without limitation, dip coating, spin coating, ink jet printing, letter-press printing, screen printing, doctor blade coating, roller printing, reverse-roller printing, offset lithography printing, flexographic printing, web printing, spray coating, brush coating, or pad printing. Very preferred solution deposition techniques are spin coating, flexographic printing and inkjet printing.

In an OFET device according to the present invention, the dielectric material for the gate insulator layer is preferably an organic material. It is preferred that the dielectric layer is solution coated which allows ambient processing, but could be also deposited by various vacuum deposition techniques. When the dielectric is being patterned, it may perform the function of interlayer insulation or act as gate insulator for an OFET. Preferred deposition techniques include, without limitation, dip coating, spin coating, ink jet printing, letter-press printing, screen printing, doctor blade coating, roller printing, reverse-roller printing, offset lithography printing, flexographic printing, web printing, spray coating, brush coating or pad printing. Ink-jet printing is particularly preferred as it allows high resolution layers and devices to be prepared. Optionally, the dielectric material could be cross-linked or cured to achieve better resistivity against solvents and/or structural integrity and/or to enable patternability (photolithography). Preferred gate insulators are those that provide a low permittivity interface to the organic semiconductor.

Suitable solvents are selected from solvents including but not limited to hydrocarbon solvents, aromatic solvents, cycloaliphatic cyclic ethers, cyclic ethers, acetated, esters, lactones, ketones, amides, cyclic carbonates or multi-component mixtures of the above. Examples of preferred solvents include cyclohexanone, mesitylene, xylene, 2-heptanone, toluene, tetrahydrofuran, MEK, MAK (2-heptanone), cyclohexanone, 4-methylanisole, butyl-phenyl ether and cyclohexylbenzene, very preferably MAK, butyl phenyl ether or cyclohexylbenzene.

The total concentration of the respective functional material (OSC or gate dielectric) in the formulation is preferably from 0.1 to 30 wt. %, preferably from 0.1 to 5 wt. %. In particular organic ketone solvents with a high boiling point are advantageous for use in solutions for inkjet and flexographic printing.

When spin coating is used as deposition method, the OSC or dielectric material is spun for example between 1000 and 2000 rpm for a period of for example 30 seconds to give a layer with a typical layer thickness between 0.5 and 1.5 μm. After spin coating the film can be heated at an elevated temperature to remove all residual volatile solvents.

For cross-linking, the cross-linkable dielectric material after deposition is preferably exposed to electron beam or electromagnetic (actinic) radiation, like for example X-ray, UV or visible radiation. For example, actinic radiation can used having a wavelength of from 50 nm to 700 nm, preferably from 200 to 450 nm, most preferably from 300 to 400 nm. Suitable radiation dosages are typically in the range from 25 to 3,000 mJ/cm². Suitable radiation sources include mercury, mercury/xenon, mercury/halogen and xenon lamps, argon or xenon laser sources, x-ray, or e-beam. The exposure to actinic radiation will induce a cross-linking reaction in the cross-linkable groups of the dielectric material in the exposed regions. It is also possible for example to use a light source having a wavelength outside the absorption band of the cross-linkable groups, and to add a radiation sensitive photosensitizer to the cross-linkable material.

Optionally the dielectric material layer is annealed after exposure to radiation, for example at a temperature from 70° C. to 130° C., for example for a period of from 1 to 30 minutes, preferably from 1 to 10 minutes. The annealing step at elevated temperature can be used to complete the cross-linking reaction that was induced by the exposure of the cross-linkable groups of the dielectric material to photoradiation.

All process steps described above and below can be carried out using known techniques and standard equipment which are described in prior art and are well-known to the skilled person. For example, in the photoirradiation step a commercially available UV lamp and photomask can be used, and the annealing step can be carried out in an oven or on a hot plate.

The thickness of a functional layer (OSC layer or dielectric layer) in an electronic device according to the present invention is preferably from 1 nm (in case of a monolayer) to 10 μm, very preferably from 1 nm to 1 μm, most preferably from 5 nm to 500 nm.

Various substrates may be used for the fabrication of organic electronic devices, for example silicon wafers, glass or plastics, plastics materials being preferred, examples including alkyd resins, allyl esters, benzocyclobutenes, butadiene-styrene, cellulose, cellulose acetate, epoxide, epoxy polymers, ethylene-chlorotrifluoro ethylene, ethylene-tetra-fluoroethylene, fibre glass enhanced plastic, fluorocarbon polymers, hexafluoropropylenevinylidene-fluoride copolymer, high density polyethylene, parylene, polyamide, polyimide, polyaramid, polydimethylsiloxane, polyethersulphone, poly-ethylene, polyethylenenaphthalate, polyethyleneterephthalate, polyketone, polymethylmethacrylate, polypropylene, polystyrene, polysulphone, polytetrafluoroethylene, polyurethanes, polyvinylchloride, silicone rubbers, and silicones.

Preferred substrate materials are polyethyleneterephthalate, polyimide, and polyethylenenaphthalate. The substrate may be any plastic material, metal or glass coated with the above materials. The substrate should preferably be homogeneous to ensure good pattern definition. The substrate may also be uniformly pre-aligned by extruding, stretching, rubbing or by photochemical techniques to induce the orientation of the organic semiconductor in order to enhance carrier mobility.

Unless the context clearly indicates otherwise, as used herein plural forms of the terms herein are to be construed as including the singular form and vice versa.

It will be appreciated that variations to the foregoing embodiments of the invention can be made while still falling within the scope of the invention.

Each feature disclosed in this specification, unless stated otherwise, may be replaced by alternative features serving the same, equivalent or similar purpose. Thus, unless stated otherwise, each feature disclosed is one example only of a generic series of equivalent or similar features.

All of the features disclosed in this specification may be combined in any combination, except combinations where at least some of such features and/or steps are mutually exclusive. In particular, the preferred features of the invention are applicable to all aspects of the invention and may be used in any combination. Likewise, features described in non-essential combinations may be used separately (not in combination).

It will be appreciated that many of the features described above, particularly of the preferred embodiments, are inventive in their own right and not just as part of an embodiment of the present invention.

Independent protection may be sought for these features in addition to or alternative to any invention presently claimed.

The invention will now be described in more detail by reference to the following examples, which are illustrative only and do not limit the scope of the invention.

The following parameters are used:
μ_{LIN} is the linear charge carrier mobility
μ_{SAT} is the saturation charge carrier mobility
W is the length of the drain and source electrode (also known as “channel width”)
L is the distance between the drain and source electrode (also known as “channel length”)
I_{D} is the source-drain current
C_{OX} is the capacitance per unit area of the gate dielectric
V_{G} is the gate voltage
V_{DS} is the source-drain voltage
Sqrt(ID) is the linear charge carrier mobility

Unless stated otherwise, all specific values of physical parameters like the permittivity (∈), charge carrier mobility (μ), solubility parameter (δ) and viscosity (η) as given above and below refer to a temperature of 20° C. (+/−1° C.), and percentages are given as % by weight.

### Example 1

Top gate OFET devices are prepared as follows.

Copper electrodes are deposited on glass substrates via a thermal evaporation process with a metal shadow mask on top of the substrate. After that, the substrates are cleaned by dipping into 1% acetic acid for 5 min followed by rinsing with DI water for several times. Then this precleaned copper substrates are immersed into an 0.0001 M AgNO₃ bath for different periods of time (in this case, t=2, 3 and 4 min) and subsequently rinsed with DI water for at least 5 times. After that, the substrates are spun dry, followed by immersion of the Ag modified Cu substrates in Lisicon® M001 (commercially available from Merck KGaA, Darmstadt, Germany) for 1 min. Then the substrates are rinsed with IPA and spun dry before putting them on top of a 100° C. hotplate for 1 min.

After the Lisicon® M001 treatment an OSC formulation for top gate OFETs, Lisicon® S1200 (commercially available from Merck KGaA, Darmstadt, Germany), is spin coated onto the modified electrodes with 2000 rpm spin rate follow by 100° C. hotplate annealing for 1 min. The substrates are then transferred to deposit a dielectric layer of Lisicon® D139 (commercially available from Merck KGaA, Darmstadt, Germany) on top of the OSC layer by spin coating the dielectric at 1600 rpm for 30 sec and annealing at 100° C. for 1 min. Finally, the Cu gate electrodes are deposited on top of the dielectric layer by a thermal evaporation process using a shadow mask.

Analysis of OFET device performance is then undertaken. The results obtained are shown below.

Transistor Characterisation:

The transistors are characterised using an Agilent 4155C Semiconductor Analyser connected to the probe station equipped with a Karl Suss PH100 probe-heads.

Transistor characteristics are measured as follows:

V_{D}=−5V and V_{G} was scanned from +20V to −60V and back in 1V steps (linear mode)

V_{D}=−60V and V_{G} was scanned from +20V to −60V and back in 1V steps (saturation mode)

Mobility values were calculated using the following formulae:

Linear Mode:

$${μ}_{LIN} = - \frac{L}{W * Cox * VD} * \frac{\partial ID}{\partial VG}$$

Saturation Mode:

$${μ}_{SAT} = \frac{2 L}{W * Cox} * {( \frac{\partial sqrtID}{\partial VG} )}^{2}$$

Work Function Measurement Using Kelvin Probe:

| Sample | Work function (φ), eV |
|---|---|
| Cu after acetic acid pre-cleaning | 4.4-4.5 |
| Cu after metal exchange with AgNO₃ (3 min) | 4.3-4.4 |
| Cu after metal exchange with AgNO₃ (3 min) + | 5.2-5.3 |
| Lisicon ® M001 treatment | |

OFET Device Performance

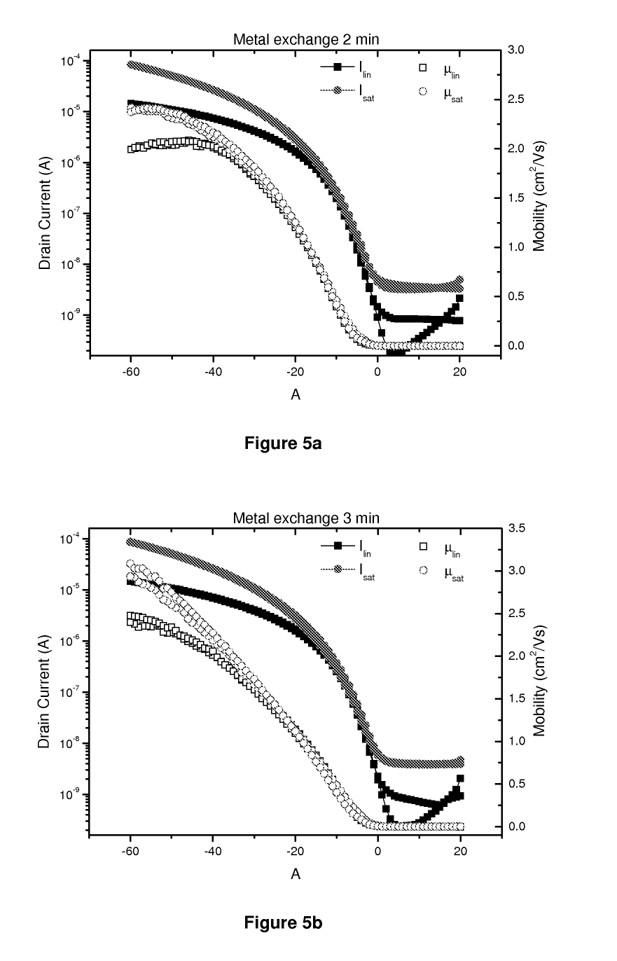

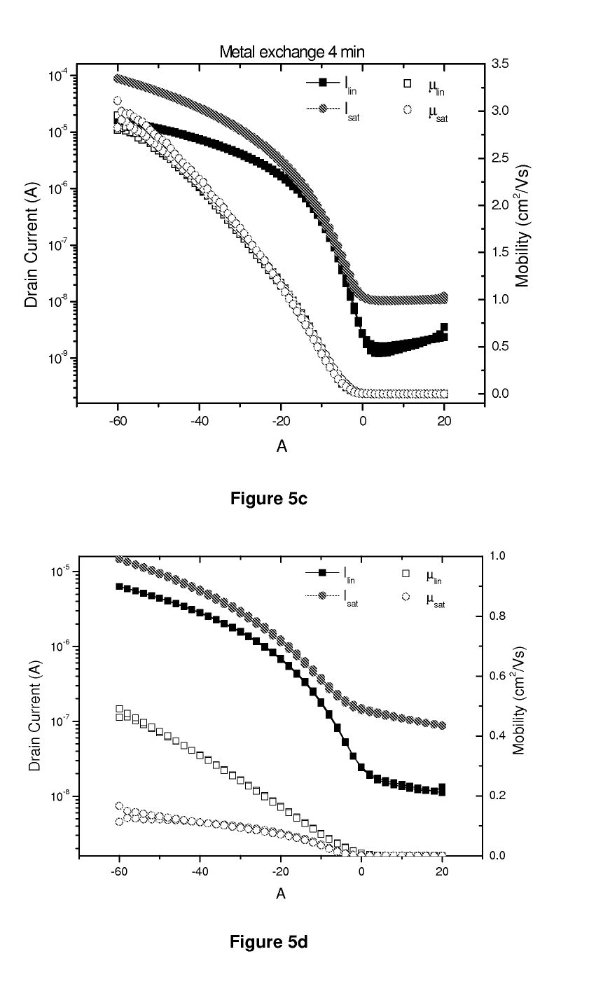

The average performance for 6 OFET devices from each individual substrate are measured and summarised. The corresponding transfer characteristics of the OFETs are shown in FIGS. 5a-d.

a) 2 min immersion on 0.1 mM AgNO₃

μₗᵢₙₑₐᵣ: 2.18 CM²/VS

μₛₐₜ: 2.08 cm²/Vs

I_{off}: 3.8×10⁻⁹ A

I_{on/off}: 1.9×10⁴

b) 3 min immersion on 0.1 mM AgNO₃

μₗᵢₙₑₐᵣ: 2.68 cm²/Vs

μₛₐₜ: 2.27 cm²/Vs

I_{off}: 4.48×10⁻⁹ A

I_{on/off}: 1.8×10⁴

c) 4 min immersion on 0.1 mM AgNO₃

μₗᵢₙₑₐᵣ: 2.32 CM²/VS

μₛₐₜ: 2.19 cm²/Vs

I_{off}: 8×10⁹ A

I_{on/off}: 9×10⁴

d) Cu with Lisicon® M001 (without any metal exchange process)

μₗᵢₙₑₐᵣ: 0.5 CM/VS

μₛₐₜ: 0.16 CM/VS

I_{off}: 10⁻¹⁰ A

I_{on/off}: 2×10⁴

These results show that the OFET devices (a-c) with Cu S/D electrodes subjected to a metal exchange process and a surface treatment process have 3 to 4 times higher mobility (μ>2 cm²/Vs), compared to the OFET device (d) with Cu S/D electrodes subjected to surface treatment but not to a metal exchange process (μ<0.5 cm²/Vs). It can also be seen that the metal exchange treatment time can vary from 2 to 4 minutes, or even longer, without changing the overall performance. This means that the process can also be used within a larger processing window.

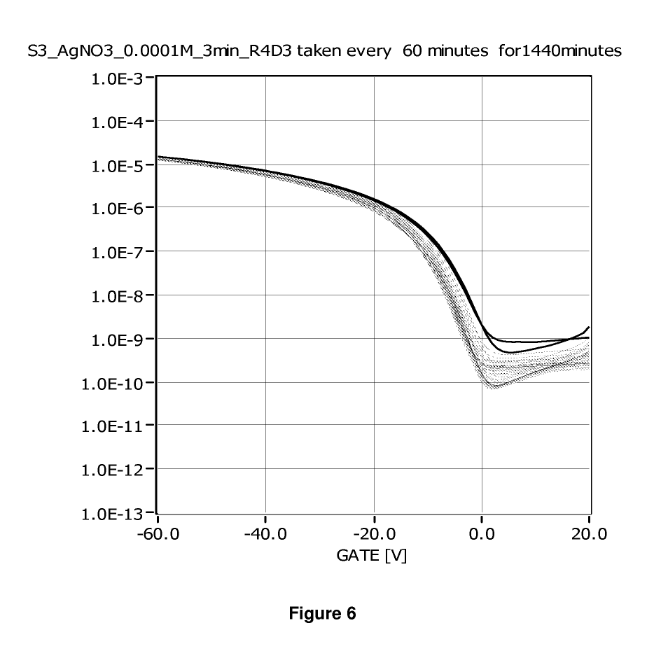

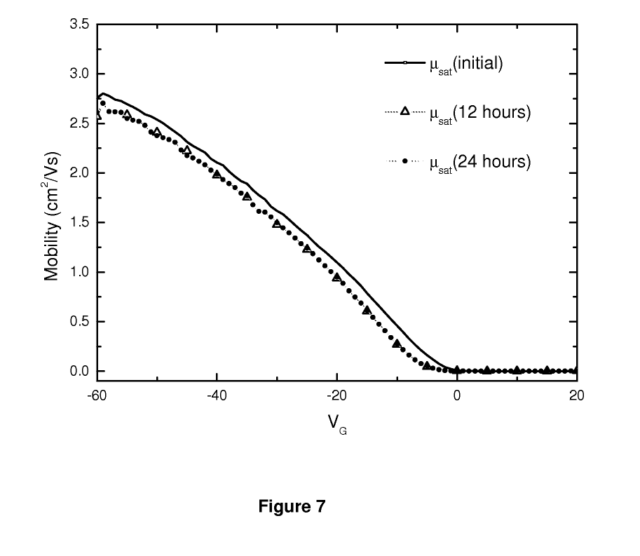

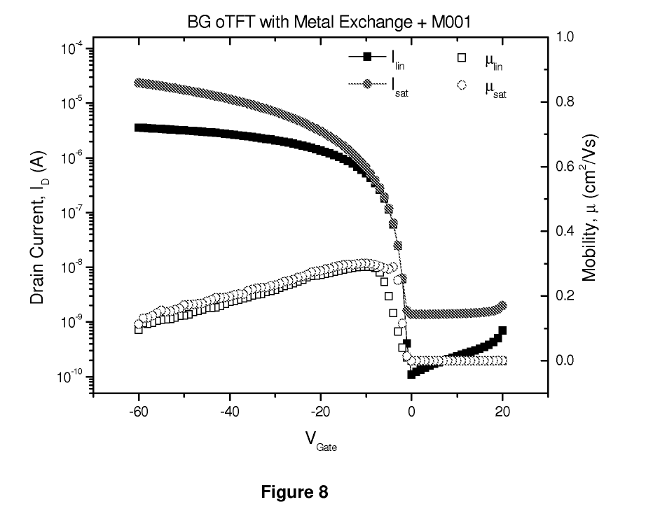

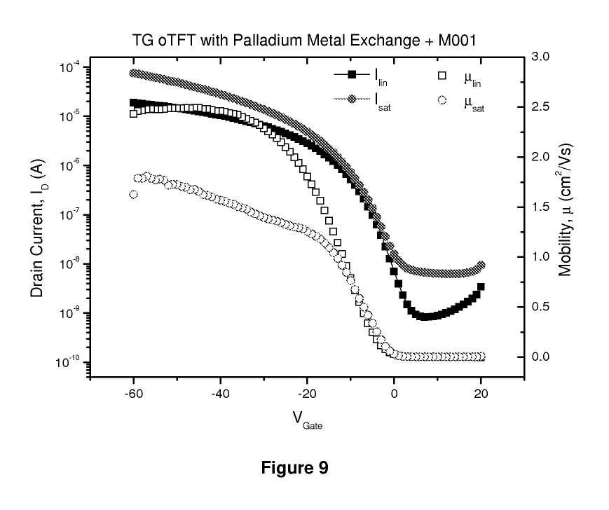

A bias stress measurement on one of the 3 min OFET devices has been performed at −60V gate voltage stress for 24 hours. The results are shown in FIGS. 6 and 7. It can be seen that in FIG. 6, the I_{D}˜8×10⁻⁴ A at V_{Gate}=−60V does not change over the time within 24 hours under the bias stress, while the I_{off} is lower over the bias stress process. This indicates that the performance of the OFET device is very consistent throughout the bias stress process, and no degradation is observed within 24 hours of stressing time. FIG. 7 illustrates the changes of saturated mobilities at the initial bias stress process and subsequent mobility for every 12 hours of bias stress. The mobility of the sample is slightly lower after 12 hours compared to the initial value. No further reduction in terms of mobility is observed between the 12 and 24 hours measurement. This indicates that no further degradation is observed after the initial stress.

### Example 2

A bottom gate (BG) OFET is fabricated as described in Example 1, using Cu S/D electrodes with a Cu—Ag metal exchange treatment and a surface treatment by Lisicon® M001 SAM layer. The basic device structure (functional layer sequence) is as follows:

Substrate/Cu(Gate)/Lisicon® D206 (gate dielectric)/Cu (S/D) with Ag metal exchange & Lisicon® M001 treatment/OSC spin coating

FIG. 8 shows the transfer characteristic for this device after 3 min of metal exchange process. The device shows a sharp turn on at V_{gate}˜0V with an average mobility of around 0.3 cm²/Vs. The on-off ratios for the saturate and linear regimes are higher than 2×10⁴.

### Example 3

A top gate (TG) OFET device is fabricated as described in Example 1, but wherein the Cu S/D electrodes are subjected to a Cu—Pd metal exchange process using an immersion bath containing Pd(NH₃)₄(NO₃)₂, followed by Lisicon® M001 surface treatment. The device performance is shown in FIG. 9.

The device shows a Vₜᵤᵣₙ₋ₒₙ at around −3V with a maximum μₗᵢₙ of 2.5 cm²/Vs and μₛₐₜ=1.8 cm²/Vs. The on-off ratio for linear and saturation regimes are higher than 10⁴. Compared to the device with Cu S/D electrodes subjected only to Lisicon® M001 treatment, the device with Cu S/D electrodes subjected to Pd metal exchange plus Lisicon® M001 treatment shows a 3 to 4 times better performance in terms of mobility.

1. Process of modifying electrodes in an organic electronic device, comprising the steps of
a) providing an electrode, or two or more electrodes, comprising a first metal,
b) depositing onto said electrode(s) a layer of a second metal having a higher normal electrode potential than the first metal,
c) optionally exposing said layer of second metal to a composition comprising an organic compound containing a functional group that interacts with the surface of said second metal, and
d) depositing onto the electrode(s), and/or in the area between said electrodes, an organic semiconductor layer.

2. Process according to claim 1, characterized in that the second metal has a higher work function than the first metal.

3. Process according to claim 1, characterized in that the first metal is selected from the group consisting of Cu, Al, Sn and Zn.

4. Process according to claim 1, characterized in that the second metal is selected from the group consisting of Ag, Au, Co, Cu, Ir, Ni, Pd, Pt, Rh and Re.

5. Process according to claim 1, characterized in that the layer of the second metal is deposited by electroless plating.

6. Process according to claim 1, characterized in that the layer of the second metal is deposited by an ion exchange process.

7. Process according to claim 1, characterized in that the layer of the second metal is deposited by immersing the electrode in a bath containing ions of the second metal.

8. Process according to claim 7, characterized in that the bath does not contain any reducing agent for the ions of the second metal.

9. Process according to claim 7, characterized in that the bath contains an organic compound containing a functional group that interacts with the surface of said second metal.

10. Process according to claim 7, characterized in that the bath contains one or more additives selected from the group consisting of ion complexing agents, buffering agents, stabilisers, salts, acids and bases,

11. Process according to claim 1, characterized in that the second metal has a similar or lower work function than the first metal, and onto the layer of the second metal there is applied a self assembled monolayer of an organic compound containing a functional group that interacts with the surface of said second metal.

12. Process according to claim 1, characterized in that the organic compound containing a functional group that interacts with the surface of said second metal is selected from the group consisting of aliphatic or aromatic thiols, aliphatic or aromatic dithiols, oligothiophenes, oligophenylenes, aliphatic or aromatic disulfides, cyanoquinoalkanedisulfide, silanes, chlorosilanes, silazanes, hexamethyldisilizane (HMDS), triazoles, tetrazoles, imidazoles and pyrazoles, carboxylic acids like for example eicosanoic acid, phosphonic acids, phosphonates, 9-anthracene phosphonate, all of which are optionally substituted, metal oxides, silver oxide and molybdenum oxide.

13. Process according to claim 1, additionally comprising the steps of depositing a gate insulator layer onto the OSC layer, depositing a gate electrode onto the gate insulator layer, and optionally depositing a passivation layer onto the gate electrode.

14. Process of preparing an organic electronic device, comprising a process according to claim 1.

15. Organic electronic device obtainable or obtained by a process according to claim 14.

16. Organic electronic device according to claim 15, characterized in that it is an organic field effect transistor (OFET), organic thin film transistor (OTFT), component of integrated circuitry (IC), radio frequency identification (RFID) tag, organic light emitting diode (OLED), electroluminescent displays, flat panel display, backlight, photodetector, sensor, logic circuit, memory element, capacitor, organic photovoltaic (OPV) cell, charge injection layer, Schottky diode, planarising layer, antistatic film, conducting substrate or pattern, photoconductor, photoreceptor, electrophotographic device or xerographic device.

17. Electronic device according to claim 15, characterized in that it is a top gate or bottom gate OFET.
